(19) United States
(12) Patent Application Publication
(10) Pub. No.: US 2014/0028405 A1
(43) Pub. Date: Jan. 30, 2014

(54) LOW POWER MICROFABRICATED ATOMIC CLOCK

(71) Applicant: John H. Hong, San Clemente, CA (US)

(72) Inventor: John H. Hong, San Clemente, CA (US)

(73) Assignee: QUALCOMM INCORPORATED, San Diego, CA (US)

(21) Appl. No.: 13/594,384

(22) Filed: Aug. 24, 2012

Related U.S. Application Data
(60) Provisional application No. 61/676,700, filed on Jul. 27, 2012.

(51) Int. Cl. H03L 7/26

(52) U.S. Cl. CPC H03L 7/26
USPC 331/94.1

(57) ABSTRACT

A low power microfabricated atomic clock generates a Coherent Population Trapping resonance. An absorption cell is disposed within a resonator cavity of a Fabry-Perot (FP) resonator or an optical ring resonator to enhance a modulation term of a transmittance. A modulated laser source, external to the resonator, is configured to excite the resonator and the absorption cell with a laser beam passing therethrough. A detector then determines a frequency associated with the CPT resonance of laser light exiting the resonator, and a frequency controller is coupled to the detector to adjust the modulated laser source based on the determined frequency. First and second quarter wave plates are positioned adjacent to respective first and second sides of the resonator.

### CLAIM OF PRIORITY UNDER 35 U.S.C. §119

The present application for patent claims priority to Provisional Application No. 61/676,700 entitled “LOW POWER MICROFABRICATED ATOMIC CLOCK” filed Jul. 27, 2012, and assigned to the assignee hereof and hereby expressly incorporated by reference herein.

### FIELD OF DISCLOSURE

This disclosure generally relates to compact atomic clocks that can provide an accurate time reference while having reduced power consumption. More particularly, this disclosure relates to microfabricated atomic clocks having a physics package volume on the order of a cubic centimeter or less, appropriate for mobile applications.

### BACKGROUND

A number of applications widely used in mobile devices may benefit from a highly accurate time base provided by a precision oscillator. Mobile devices incorporating position location systems, such as GPS, and/or communications systems traditionally utilize voltage controlled temperature compensated crystal oscillators (VC-TCXO) as a timing reference due to their small size, low cost, and low power consumption. While the accuracy and stability of VC-TCXOs are typically sufficient for most applications, improvements in performance and speed may be realized using oscillators having greater precision. Such improvements can lead to faster GPS fixes, new security capabilities, etc.

Recent advances in the miniaturization of atomic clocks appear to provide a promising new timekeeping alternative having significantly better precision than existing VC-TCXOs. These miniaturized atomic clocks may be referred to as microfabricated atomic clocks. Miniaturized atomic clocks utilizing components manufactured with microelectromechanical system fabrication techniques (MEMs) offer smaller size, lower power dissipation, and options for wafer-level integration. MEMs structures can include structures having sizes ranging from about a micron to hundreds of microns or more. Likewise, nanoelectromechanical systems (NEMS) can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices. Microfabricated atomic clocks may include MEMs or NEMs components. Likewise, microfabricated atomic clocks may be generally referred to as Chip Scale Atomic Clocks (CSACs), and such terms are used interchangeably throughout.

In general, an atomic clock uses a transition frequency in the microwave, optical, or ultraviolet region of the electromagnetic spectrum of atoms as a frequency standard for its timekeeping element. The principle of operation is not based on nuclear physics, but rather on atomic physics, and uses an electromagnetic signal (usually a microwave signal) that electrons in atoms emit when they change energy levels. Controlling and detecting this change in energy levels produces the reference for the timekeeping element.

In general, the core of an atomic clock is a cavity containing a gas such as Cesium or Rubidium. The gas absorbs energy from a laser diode which is optically modulated in response to an oscillator. The gas then changes between energy levels and energy output from the cavity is determined by a detector. The oscillator is generally controlled by a feedback signal from the detector that keeps the oscillator tuned in resonance with the changing energy levels. The output form the detector is then used as a timing reference.

### SUMMARY

Exemplary embodiments of the invention are directed to systems and methods for a low power Chip Scale Atomic Clock (CSAC). Embodiments of the disclosure are directed to microfabricated atomic clocks that may have an absorption cell placed within a resonator cavity to reduce the size of the absorption cell. Placing the absorption cell within a resonator allows a modulated laser beam to pass through the absorption cell multiple times, thus permitting multiple interrogations of the absorption cell by recirculating the excitation light.

According to an embodiment, a coherent population trapping mechanism is used to realize a compact atomic clock. An absorption cell, with a suitable concentration of rubidium atoms in the vapor phase, is placed in the path of a laser beam. The laser beam frequency coincides with one of two well known transitions from the ground state to an excited state (valence electron). The absorption cell absorbs the laser light and a transmitted beam output from the absorption cell is detected with a photodetector. Alternately, instead of a single frequency laser beam, two mutually coherent laser beams pass through the absorption cell, with the average frequency matching the transition frequency but the difference frequency matching the hyperfine splitting between the two ground state configurations (electron spins). A coherence state is then produced in the atomic species and the transition to the excited state is blocked. Accordingly, a drop is observed in the absorption that is a very sensitive function of the difference frequency of the two laser beams. The two laser beam frequencies may be produced by a single semiconductor laser having an associated pump current modulated by the desired difference frequency. This produces, in a single spatial beam, both frequencies needed for the CPT effect to be observed. A limit to power dissipation is related to an ability of the photodetector to register a drop in the absorption with sufficient SNR to allow phase locking to occur. This translates directly to a minimum volume of atomic gas which must be provided in a temperature controlled setting (i.e., oven).

According to an embodiment, a laser, atomic vapor cell, and photodetector are incorporated into a single device. The laser beam is recirculated through the absorption cell multiple times. The absorption cell may be placed in an optical cavity. The laser beam is then coupled into the cavity and the light inside the cavity passes through the absorption cell many times, back and forth, as allowed by the Q of the optical cavity. This immediately reduces the volume requirement on the absorption cell (atomic concentration) because the absorption requirement is reduced by the Q factor. Accordingly, integration of functions necessary for atomic clock operation using coherent population trapping are provided along with reductions in the power needed to have sufficient laser power and sufficient vapor pressure in the atomic clock.

In one embodiment, a CSAC based upon generating a Coherent Population Trapping (CPT) resonance is presented. CPT interrogates the ground-state hyperfine resonance of an atomic vapor pressurized in an absorption cell. The chip scale atomic clock may include a Fabry-Perot (FP) resonator configured to enhance a modulation term of a transmittance. The CSAC may further include a first quarter wave plate adjacent to a first side of the FP resonator, an absorption cell placed inside the cavity of the FP resonator, and a second quarter wave plate adjacent to a second side of the FP resonator. The CSAC may further include a modulated laser source, external to the FP resonator, configured to excite the FP resonator and the absorption cell with a laser beam passing through the first quarter wave plate, a detector configured to determine a frequency associated with the CPT resonance of the laser light exiting the FP resonator and passing through the second quarter wave plate. The CSAC may also include a frequency controller functionally coupled to the detector, which adjusts the modulated laser source based on the determined frequency.

In another embodiment, a chip scale atomic clock may include a resonator configured to enhance a modulation term of a transmittance, an absorption cell placed inside the resonator; a first quarter wave plate associated with a first side of the absorption cell; a second quarter wave plate associated with a second side of the absorption cell; a modulated laser source, external to the resonator, configured to excite the resonator and the absorption cell with a laser beam passing through the first quarter wave plate and the second quarter wave plate; a detector configured to determine a frequency associated with the CPT resonance of the laser light exiting the resonator; and a frequency controller functionally coupled to the detector, which adjusts the modulated laser source based on the determined frequency. In an embodiment, the resonator may include a ring resonator waveguide coupled to an input waveguide through an evanescent coupling, with the input waveguide coupled to the modulated laser source at one end, and the detector at an opposite end. In another embodiment, the resonator may include a Fabry-Perot (FP) resonator configured to enhance a modulation term of a transmittance.

In yet another embodiment, a method of generating a reference oscillating signal based on CPT resonance is presented. The method may include modulating a laser beam to produce frequencies associated with ground state hyperfine transition levels, and exciting an absorption cell placed within a resonator with the modulated laser beam, where a source for the modulated laser beam is external to the resonator. The method may further include detecting a frequency associated with the CPT resonance of the laser light exiting the resonator, and controlling the modulation of the laser beam based on the detected frequency.

### BRIEF DESCRIPTION OF THE DRAWINGS

The accompanying drawings are presented to aid in the description of embodiments of the invention and are provided solely for illustration of the embodiments and not limitation thereof.

FIG. 1 is a block diagram illustrating a Chip Scale Atomic Clock (CSAC) 100 which uses Coherent Population Trapping (CPT).

FIG. 2 is a drawing depicting an embodiment of an absorption loaded Fabry-Perot (FP) cell.

FIG. 3 is a plot illustrating the transmittance of the absorption loaded FP cell and the local slope, both as a function of the transmittance of the absorption cell.

FIG. 4 is a block diagram of an exemplary CSAC based on CPT using an absorption loaded FP cell.

FIGS. 5A and 5B are block diagrams illustrating different embodiments for a modulated laser source.

FIG. 6 is a block diagram of an exemplary absorption loaded FP cell utilizing an interferometric technique to enhance absorption.

FIG. 7 is a block diagram of an exemplary CSAC which may utilize an absorption cell embedded in a ring resonator.

FIGS. 8A and 8B illustrate different cross sections of the ring resonator shown in FIG. 7.

FIG. 9 is a diagram illustrating production of a quarter wave plate using holograph birefringence.

FIG. 10 is a flow chart illustrating a method for generating a reference oscillating signal based on CPT.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Embodiments of the disclosure are directed to chip scale atomic clocks (CSACs) which may have an absorption cell placed within a resonator cavity to reduce the size of the absorption cell. Placing the absorption cell within a resonator allows a modulated laser beam to pass through the absorption cell multiple times, thus permitting multiple interrogations of the absorption cell by recirculating the excitation light. This approach may improve efficiency because traditional CPT approaches are directed towards techniques for utilizing a single pass of the laser beam through the absorption cell. The efficiencies gained through recirculation of the excitation laser beam can present several benefits. One benefit is that the actual length L of the absorption cell (and thus its associated volume) may be reduced. This reduction in actual length occurs because the resonance (“Q”) of the resonating cavity increases the effective length of the absorption cell. The reduced volume of the absorption cell may require less power to heat the vapor within the absorption cell. Moreover, the recirculation of the laser light also may permit a reduction of the laser power used for excitation of the absorption cell. This reduction in power consumption may be significant, and allow CSACs to consume less than 1 uW (1×10⁻⁶ Watts) of power. Additionally, the reduced volume of the absorption cell can lead to reductions in size of the entire CSAC package. The reductions in both power consumption and size of the CSAC may be advantageous in mobile applications, where power budgets and sizing constraints can be design drivers in, for example, handheld communications, and/or navigation devices.

Accordingly, apparatuses and methods presented below may be used to further reduce the size of the absorption cell to improve packaging and reduce power consumption. The absorption cell presents a loss to light traveling therethrough. Because cell length is related to absorption, an increase in cell length provides greater absorption. However, absorption may also be increased by enhancing atomic absorption modulation for an absorption cell. This can permit a smaller cell to be used. The power transmittance through the cell, T_{A}, may be described by the exponential loss term:

T_{A}=e^{-αL=e}^{-(α}^{₀}^{+Δα)L}≈e^{-α}^{_{L}}(1−ΔαL)

where L is the vapor cell length, α₀ is the average absorption and Δα represents the fluctuating term (depends on whether or not the two optical frequencies match the transparency inducing effect associated with coherent population trapping). The fluctuation term Δα may be “amplified” so that CPT absorption becomes more easily detectable (i.e., provide a “high contrast” CPT signal). Approaches for increasing the detectability of the CPT absorption are particularly described in greater detail below as: 1. an absorption loaded Fabry-Perot resonator; and 2. a circular optical waveguide resonator.

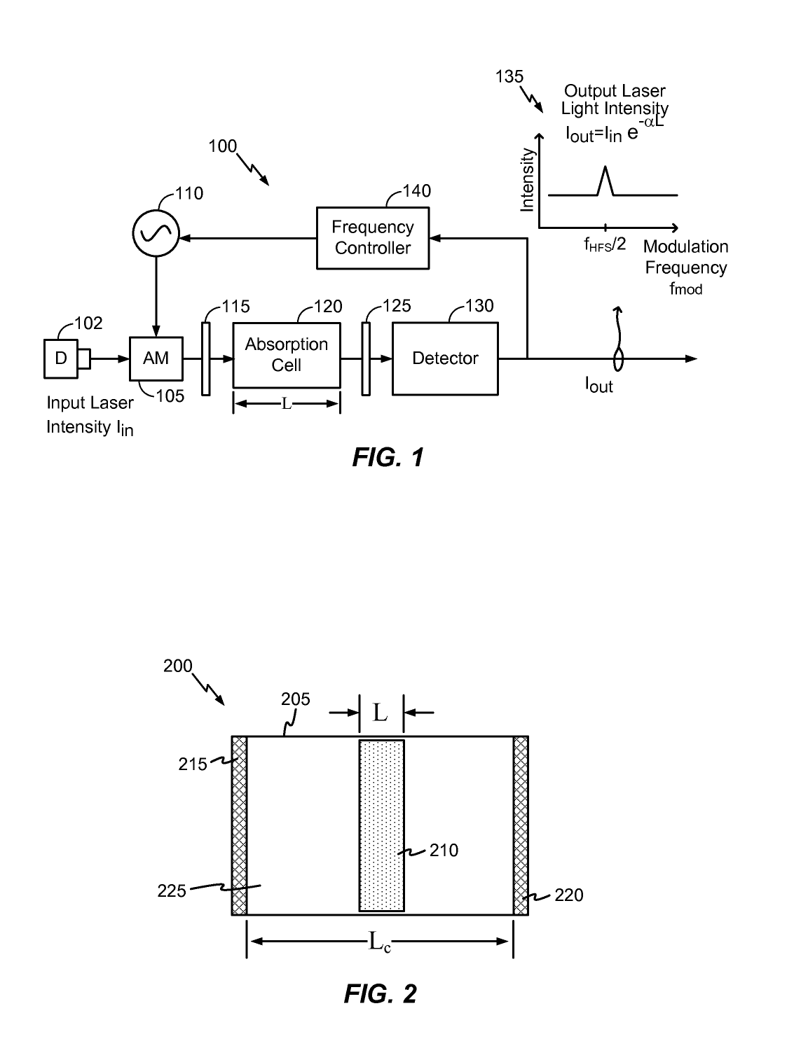

FIG. 1 illustrates CSAC 100 which uses CPT to access hyperfine splitting microwave transition by optical absorption tuning (A transition). During operation, the CSAC 100 may use a laser diode (D) 102 to generate an input laser beam having intensity Iᵢₙ. The input laser beam may then be modulated by an optical amplitude modulator (AM) 105 using microwave modulation provided by oscillator 110 to produce a modulated laser beam. The frequency of the oscillator 110 may correspond to half the ground state hyperfine frequency of the material (e.g., gas) in an absorption cell. The polarization of the modulated laser beam may be converted from a linear polarization to a circular polarization by quarter wave plate 115. The modulated, circularly polarized laser beam then may interrogate an absorption cell 120. The absorption cell has a length L, and may contain an atomic vapor derived from a Rubidium or Cesium sample. The atomic vapor within heating absorption cell 120 may be heated, and may be heated between 108-110 degrees Celsius.

In CSAC 100, the modulated, circularly polarized laser light makes one pass through the atomic vapor in the absorption cell 120. Afterward, the light exiting the absorption cell 120 is converted back to linear polarization by second quarter wave plate 125, and then collected by a detector 130. The detector 130 has a response time which is faster than the frequencies associated with the microwave modulation. The absorption cell 120 has an absorption peak governed by the excitation of the valence electron to upper levels. Coherent Population Trapping (CPT) prepares a coherent quantum state accessed by two optical fields, which are mutually coherent but separated by the ground state hyperfine splitting frequency f_{HFS} (as provided by the modulated laser output from AM module 105). Denoting the modulation frequency as f_{mod} (equivalently, half the difference frequency between the two sideband optical fields), CPT resonance occurs when 2f_{mod}=f_{HFS}. If this condition is met, the absorption at the ground state hyperfine frequency drops because the transition from that superposed quantum state is not allowed. The decrease in absorption at that frequency corresponds to a peak in the intensity seen at detector 130. This is illustrated in FIG. 1, graph 135, which displays intensity as a function of f_{mod}. The peak transmission amplitude corresponding to CPT resonance in the absorption cell occurs when the two laser field frequencies match the two transitions between the two hyperfine split ground states and a common excited state. It is desirable to have a sharp, narrow peak (i.e., “high contrast”) in order to more easily determine f_{HFS}, which is the difference in the frequencies of the two transitions, and control the modulation frequency to match. A feedback loop using frequency controller 140 controls the modulation frequency of the laser beam by varying the oscillator 110 frequency provided to optical amplitude modulator 105. The feedback loop permits CSAC 100 to achieve and maintain an accurate frequency lock, thus implementing the clock functionality.

At room temperature, the vapor pressure in the absorption cell may be low, and thus the CPT absorption signal may be weak and the peak seen at detector 130 exhibits low contrast. The contrast of the CPT peak improves as a function of increasing vapor pressure in absorption cell 120. As noted above, to increase vapor pressure, the Rubidium or Cesium sample is typically heated to generate a desired vapor pressure for improving the CPT signal contrast. The energy used in the heating process may be a significant source of power dissipation, and may present a challenge for managing power within a mobile device. However, the energy used to heat absorption cell 120 scales with size, and hence a smaller cell uses less energy. Additionally, the CPT contrast may also be improved by increasing the length (L) of the absorption cell 120.

### 1. Absorption Loaded Fabry-Perot Resonator

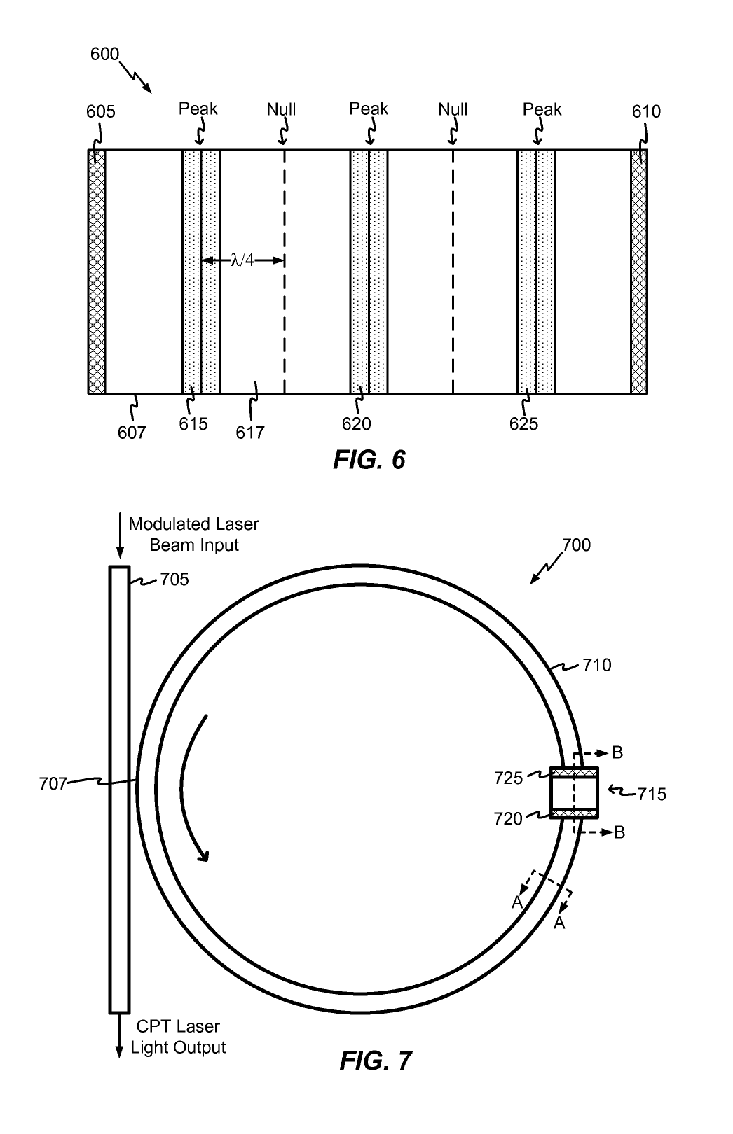

FIG. 2 is a drawing depicting an embodiment of an absorption loaded Fabry-Perot (FP) cell 200. The absorption loaded FP cell 200 may include a Fabry-Perot (FP) resonator 205, which further includes partially reflecting mirrors 215 and 220 on each side of cavity 225. An absorption cell 210 may be placed within cavity 225 of the FP resonator 205. The absorption cell 210 may be generally placed at any location within cavity 225. However, in some embodiments, particular placement of one or more absorption cells may be employed, as will be explained in more detail below with reference to FIG. 6. In other embodiments, an absorption loaded FP cell may be realized using non-rectangular shapes, such as, spherical and/or other curved shapes. Curved absorption loaded FP cells may be used when the cell is sufficiently long and diffraction loss is to be controlled.

The absorption cell 210 will have a length L, which may lie within the range of 0.01 to 1 mm, and may be smaller in terms of volume than conventional absorption cells by a factor of 10-100. In principle, the absorption cell 210 length L can be several wavelengths long (e.g., approximately 10× wavelengths), and on the order of a wavelength in cross section. The absorption cell 210 may contain an atomic vapor derived from, for example, a Rubidium or Cesium sample. The atomic vapor may be generated and/or enhanced by heating absorption cell 210. In other embodiments, the absorption cell 210 may be realized as a solid state cell. The FP resonator 205 and/or absorption cell 210 are components that may be fabricated using integrated circuit and/or MEMS techniques.

The mirrors 215, 220 may be partially reflecting to permit some laser light to enter and escape the cavity 225, and may have a reflectivity given by R_{M} (e.g., power ratio, which may be 90%). The length of the cavity 225 is given by L_{C}. The absorption cell transmittance (power ratio of transmitted to input) given by T_{A} (from the equation provided above) and the wavelength of light given by λ (a typical wavelength may be 795 nm for example, to use the D₁ transition in ⁸⁵Rb). The transmittance T_{FP} through the absorption loaded FP cell 200 may be modeled as:

$${T}_{FP} = \frac{{( 1 - {R}_{M} )}^{2} {T}_{A}}{1 + {R}_{M}^{2} {T}_{A} - 2 {R}_{M} \sqrt{{T}_{A}} cos ( \frac{4 π {L}_{C}}{λ} )}$$

The cavity length L_{c} can be tuned so as to keep the absorption loaded FP cell 200 biased at the peak transmittance (i.e., T_{FP} is maximum as a function of λ). The length L_{c} of cavity 225 may be an integer multiple of the half-wavelength of the excitation laser beam. The integer multiple does not provide a first order difference, except that increases in cavity size may present additional challenges for system stabilization. The absorption in an absorption cell (whether it is vapor phase or solid) should be minimized to keep the interaction length small, thereby keeping transmittance T_{A} closer to a value of 1. In some embodiments, the absorption loaded FP cell 200 may have a cavity 225 that can extend into the surface of the mirrors 215, 220, depending upon how the mirrors 215, 220 are fabricated.

In other embodiments, the FP resonator 205 can include photonic band gaps within a bulk dielectric having periodic holes forming a lattice in three dimensions. The cavity 225 in such a case would be a defect in the lattice, which allows light to be localized leading to resonance.

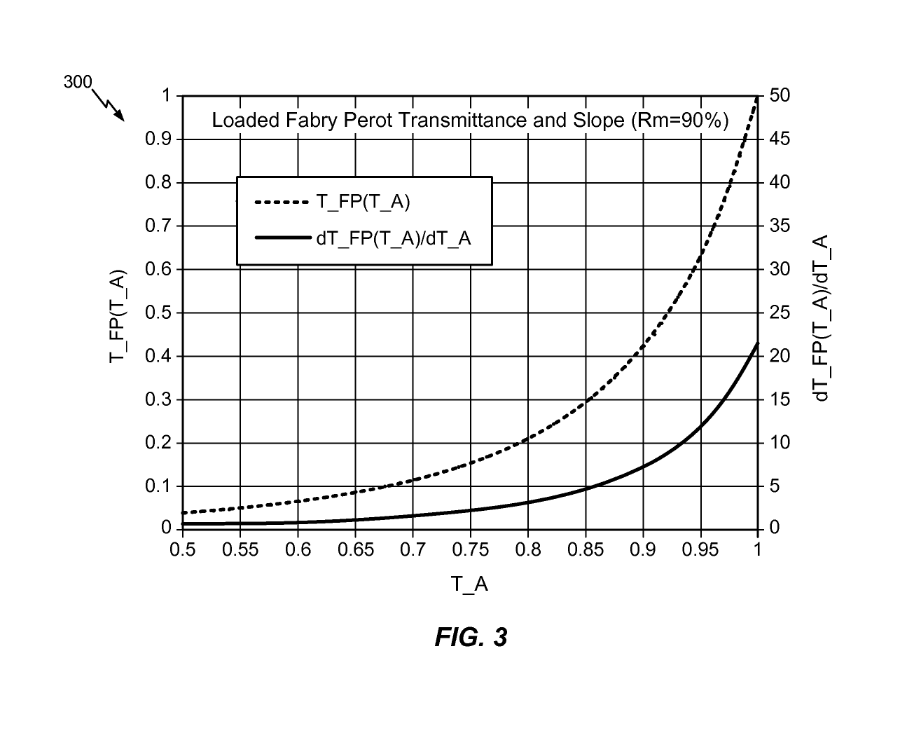

FIG. 3 is a plot 300 illustrating the transmittance of the absorption loaded Fabry-Perot cell (T_FP—dashed curve) and the local slope (dT_FP—solid curve), both as a function of the transmittance of the absorption cell. The vertical axis on the left is the transmittance through the absorption loaded Fabry-Perot cell 200, and the horizontal axis is the single pass transmittance through the absorption cell 210. For the horizontal axis, the value of 0.5 (on the left side of the plot) implies that half the power passes through the absorption cell (that is, half the power is absorbed), and the value 1 (on the right) implies that all of the light energy passes through the absorption cell (that is, no absorption).

The mirror reflectivity used in these plots is 90% for each mirror. The local slope of the transmittance curve is an important parameter because a fluctuation in transmittance gives rise to a clock error signal. The slope can be increased by utilizing higher reflectivity mirrors, enhancing the Q of the cavity and realizing a large number of multiple passes through the same cell. As a way of comparison, without a cavity, the slope of the absorption cell is unity. Hence, there is generally an enhancement factor from the use of the Fabry-Perot resonator 205 alone.

The slope shown in the solid curve is notable, as the loaded FP absorption cell should operate in the region where the slope is larger (on the right hand side) to be able to improve CPT detection when modulating absorption through the absorption cell. In other words, configure the FP resonator 205 to enhance the modulation term Δα by selecting a particular T_A value, so that small modulations on the input result in a large change in the output for easier CPT detection.

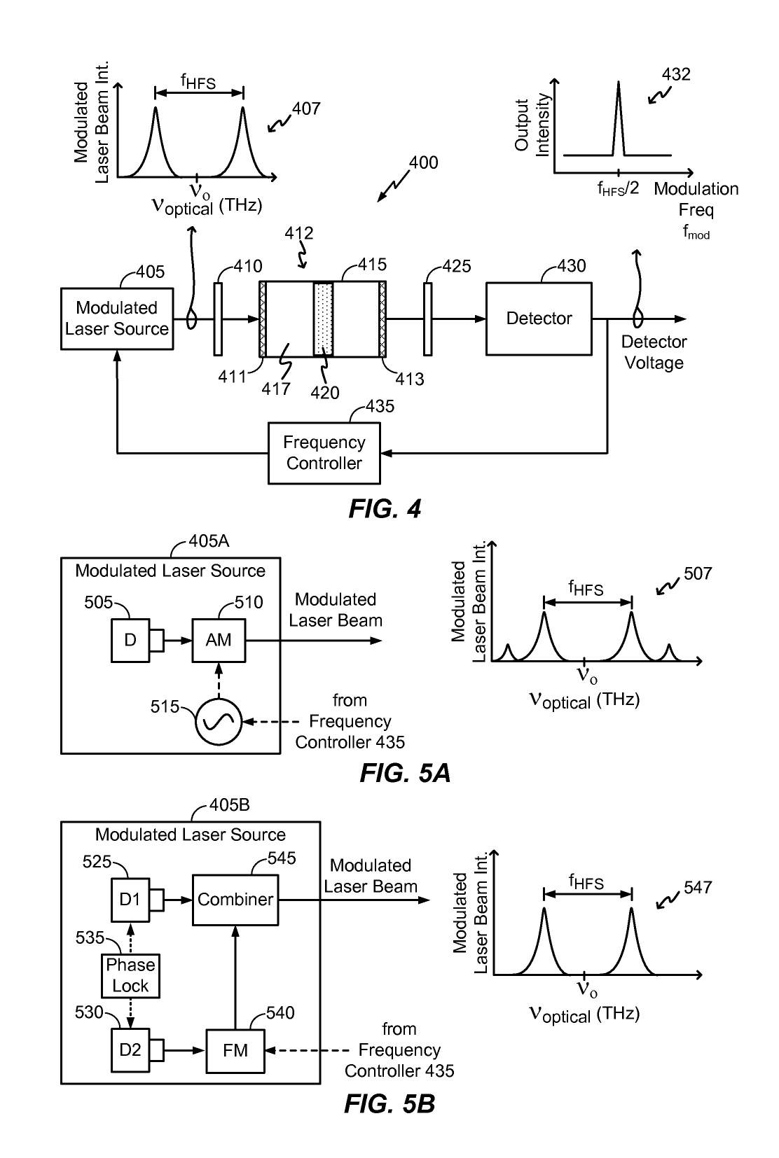

FIG. 4 is a block diagram of an exemplary chip scale atomic clock (CSAC) 400 based on CPT using an absorption loaded Fabry-Perot cell 412. The CSAC 400 may include a modulated laser source 405, a first quarter wave plate 410, the absorption loaded FP cell 412, which may further include an FP resonator 415 and at least one absorption cell 420. The absorption loaded FP cell 412 may include partially reflecting mirrors 411, 413 disposed on alternate sides of cavity 417. The CSAC 400 may further include a second quarter wave plate 425, a detector 430, and a frequency controller 435.

The CSAC 400 may utilize a modulated laser source 405 to provide an input laser beam used to excite the absorption loaded FP cell 412. As illustrated in plot 407, the input laser beam may be modulated to have double sidebands around a center frequency νₒ. The peaks of the sidebands should be separated by the frequency f_{HFS}, which corresponds to the ground state hyperfine transition frequency of the atomic vapor in absorption cell 420. The modulated laser beam may then be passed through a first quarter wave plate to transform the polarization of the laser beam from linear to circular. The circularly polarized modulated laser beam may pass through partially reflecting mirror 411, and then enter FP resonator 415. Once inside cavity 417, the laser light “recirculates” in the FP resonator as it reflects off of mirrors 411 and 413, thus repeatedly interrogating absorption cell 420. A portion of the recirculating laser light escapes mirror 413 of FP resonator 415, and is passed through a second quarter wave plate 425 to transform the output laser light from circular to linear polarization. The linearly polarized light is then detected by detector 430, which may convert the output light into a corresponding voltage to produce the CPT signal as illustrated in plot 432. When the absorption loaded FP cell is interrogated properly, the CPT signal can exhibit a sharp, narrow peak at the frequency f_{mod}=f_{HFS}/2, where f_{HFS} is the frequency difference between the two ground state hyperfine split levels and the common excited state. The f_{HFS} frequency may be tracked by the frequency controller 435, and generate a signal to control the modulated laser source 405 to maintain a “lock” on the f_{HFS} frequency.

The absorption cell 420 may have a smaller volume than conventional absorption cells, and thus will typically have a shorter length L as noted above in the description of FIG. 2. In various embodiments, the absorption cell 420 may be a vapor cell, and due to its smaller volume, does not require as much power to raise the vapor pressure to establish a CPT signal having a high contrast peak. Additionally, the “Q” (or sharpness of the resonance) of the FP resonator 415 also contributes directly to the contrast of the CPT signal in plot 432. In other embodiments, the absorption cell 420 may be a solid state cell placed in the FP resonator 415.

The detector 430 may be a photo detector having sufficient bandwidth to measure the modulation frequencies, which will typically be in the microwave region. The photo detector 430 can convert the laser light to an electrical voltage (proportional to the modulation envelope of the light-wave), which may be utilized by the frequency controller 435. The output of detector 430 may then be used as a time reference signal.

Accordingly, one embodiment may be directed to an apparatus 400 for generating a reference oscillating signal based on a Coherent Population Trapping (CPT) resonance. The apparatus 400 may include a means (e.g. 405) for modulating a laser beam to produce frequencies associated with ground state hyperfine transition levels. The apparatus 400 may further include a means (e.g. 412) for exciting an absorption cell placed within a resonator with the modulated laser beam, where a source for the modulated laser beam is external to the resonator. The apparatus 400 may also include a means (e.g., 430) for detecting a frequency associated with the CPT resonance of the laser light exiting the resonator. The apparatus may further include a means (e.g., 435) for controlling the modulation of the laser beam based on the detected frequency.

FIGS. 5A and 5B are block diagrams illustrating different embodiments for the modulated laser source 405. In the embodiment of FIG. 5A, modulated laser source 405A may produce a laser beam having the appropriate sidebands using amplitude modulation. A laser source 505, which may be a laser diode D, can provide an unmodulated laser beam having a center frequency of νₒ. The unmodulated laser beam may be provided to an amplitude modulation module 510, which amplitude modulates the laser beam in response to a local oscillator 515. In this embodiment, a suppression of the optical carrier is implied using known optical techniques. The local oscillator 515 generates frequencies in the microwave range, and is controlled based on a signal provided by frequency controller 435. The local oscillator 515 may generate a sinusoidal signal having a frequency of f_{HFS}/2. However, as shown in plot 507, the modulated laser beam produced using this technique may include undesirable high frequency components in addition to the desired sidebands, which may reduce the amplitude level of the sidebands. The sidebands may be generated by nonlinearities in the amplitude modulation module 510. Additionally, insertion losses of the amplitude modulation module 510 may further reduce the amplitudes of the sidebands in the modulated laser beam. These reductions in amplitude of the modulated laser beam associated with using amplitude modulation can negatively impact the power efficiency of the CSAC 400.

In another embodiment illustrated in FIG. 5B, a modulated laser source 405B may provide greater efficiency by using two separate lasers and frequency modulation. Specifically, modulated laser source 405B may have two laser sources 525 and 530. The laser sources may be realized as laser diodes D1 and D2. The laser sources 525 and 530 may be kept at the same phase by phase lock module 535 in order to maintain phase coherence. Laser source 530 may emit a laser beam that is frequency modulated by frequency modulation block 540 to thereby shift the frequency. The frequency shifted laser beam may then be superimposed on the laser beam output by laser source 525 using a combiner 545. In one embodiment, the combiner 545 may be a separate beam splitter. In another embodiment, the resonating cavity of laser source 525 may be used, and the output laser from the frequency modulation block 540 may be introduced into the cavity of laser source 525 to perform the superposition.

While the embodiment of FIG. 5B may utilize additional components, modulated laser source 405B may avoid insertion losses caused by amplitude modulators, and thus be more efficient in terms of power consumption. Additionally, this embodiment may mitigate higher order sideband production caused by the non-linearities of amplitude modulators, as shown in plot 507. Accordingly, enhanced double sidebands may be produced around a center frequency νₒ as shown in plot 547.

FIG. 6 is a block diagram of an exemplary absorption loaded Fabry-Perot cell 600 utilizing an interferometric technique to enhance absorption. The absorption loaded FP cell 600 includes an FP resonator 607 and one or more absorption cells 615, 620, 625 in cavity 617. The FP resonator further includes mirrors 605, 610 disposed at alternative sides of cavity 617.

In the absorption loaded FP cell 600, each absorption cell may be placed in the cavity 617 at separate peaks of a standing wave established by the FP resonator 607. Specifically, each absorption cell 615, 620, 625 is placed in the cavity 617 at a different multiple of λ/4 along the length of the FP resonator 607. Such placement may also enhance the absorption in each absorption cell due to constructive interference locally maximizing the light-wave intensity. The use of more than one absorption cell, each receiving a locally maximized light-wave intensity, can realize an increase in absorption up to a factor of four over conventional single pass CPT techniques.

### 2. Optical Ring Resonator

FIG. 7 is a block diagram of an exemplary optical ring resonator 700, which includes a linear waveguide 705 coupled to ring waveguide 710 by way of an evanescent coupling 707. Absorption cell 715 is embedded in ring waveguide 710. Instead of using an FP resonator which “recirculates” the modulated laser in a linear manner between two mirrors as described above, resonator 700 uses ring waveguide 710 to perform the light recirculation function. A modulated laser source (set forth in detail above) provides a modulated input laser beam to linear waveguide 705. Through evanescent coupling 707 between linear waveguide 705 and the ring waveguide 710, the input laser beam may enter into the ring waveguide 710 and circulate in a counter clockwise direction as shown. The modulated laser beam will pass through a quarter wave plate 720 to convert the laser beam from linear to circular polarization. The circularly polarized wave will then interrogate the absorption cell 715, and pass through a second quarter wave plate 725 to convert the laser beam from circular polarization to linear polarization. As explained in greater ore detail below, the polarization conversion steps are performed by the quarter wave plates 720, 725 because circular polarization is preferred to establish CPT resonance in the absorption cell. However, linear polarization is preferred for stable propagation through the optical waveguide of the ring waveguide 710. The CPT output laser light may exit ring waveguide 710 and enter linear waveguide 705 through evanescent coupling 707. The laser light then exits out of linear waveguide 705 for subsequent detection and frequency control, thereby performing the frequency locking function of the CSAC.

Accordingly, by taking advantage of the “Q” provided by the optical ring resonator 700, the absorption cell 715 is interrogated with multiple passes of light. This may reduce the volume when compared to conventional absorption cells, which are interrogated using a single pass of a modulated laser beam.

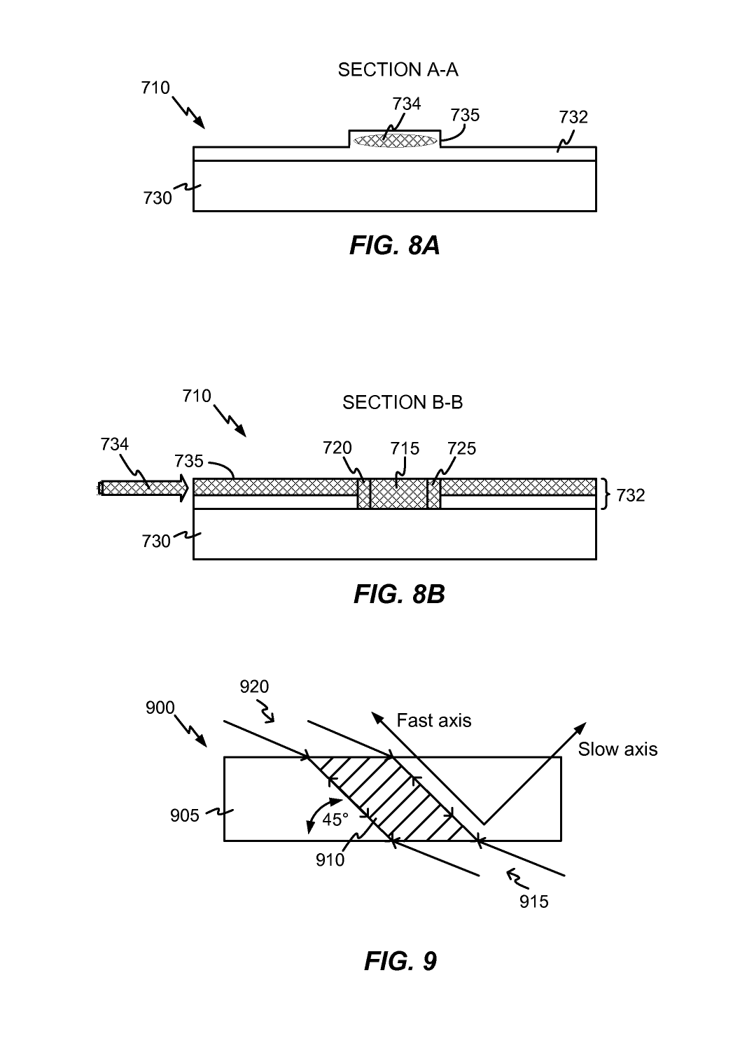

FIGS. 8A and 8B illustrate different cross sections of ring waveguide 710 of FIG. 7. FIG. 8A illustrates section A-A taken through the ring waveguide 710, as shown in FIG. 7. The waveguide 710 includes a low index substrate 730 and a patterned higher index guiding layer 732. A rib structure 735 protrudes upwardly from patterned higher index guiding layer 732 and provides confinement of a linearly polarized laser beam 734 into a definitive guided mode.

FIG. 8B illustrates section B-B, taken through ring waveguide 710 and absorption cell 715 of FIG. 7. As illustrated, absorption cell 715 is disposed between quarter wave plates 720, 725. Guiding layer 732 has rib structure 735 disposed above substrate 730. The linearly polarized laser beam 734 may enter from the left, and have its polarization transformed into circular polarization by quarter wave plate 720. The circularly polarized laser beam may interrogate absorption cell 715 to cause CPT resonance within an atomic sample disposed therein. The resulting laser beam may then be converted back to linear polarization by quarter wave plate 725, and travel along rib structure 735 of guiding layer 721, subsequently exit ring waveguide 710 through evanescent coupling 707.

### Circular Polarization and Holographically Produced Quarter Wave Plates

The atomic interaction utilized to generate the CPT signal uses a light field that is circularly polarized. By way of example, if the state of the circular polarization is RHC (right handed circular), a pair of quarter wave plates may be used to transform a given linear polarization into the RHC state before the laser beam enters the absorption cell. Likewise, a quarter wave plate with the opposite orientation (switch the orientation of the slow versus fast axes) transforms the RHC back into the original linear state. Such transformations are of interest for CSACs using an absorption loaded FP cell 412 shown in FIG. 4 or an optical ring resonator 700 shown in FIG. 7, because waveguide technologies, which may be used in either type of CSAC, may not exhibit stable waveguide modes with circular polarization states.

The polarization of optical waveguide structures as described above can be designed to have a TE mode, i.e. a transverse-electric mode, where the electric field is parallel to the substrate. Likewise, the polarization can be designed to have a TM mode, i.e. a transverse-magnetic mode, where the magnetic field is parallel to the substrate. Suppose, without loss of generality, that the polarization is TE. The quarter wave plate is then oriented such that the electric field is a 45 degree angle with respect to the plate. The first plate is oriented such that the TE polarization transforms into an RHC (right handed circular) polarization (for example, if this is the desired polarization state for interacting with the atomic vapor) and the second plate orientation is reversed so that the polarization state reverts back to the TE polarization. One technique described below may be employed to produce quarter wave plates which may be used with chip scale atomic clocks.

FIG. 9 illustrates formation of a quarter wave plate 900 by using holographic birefringence in a wave plate material 905. Two coherent laser beams 915, 920 counter-propagate through material 905 to create a holographic exposure and thereby define a high spatial frequency index grating 910. The index grating 910 has a grating vector oriented at a 45 degree angle with respect to the TE orientation. Each of the coherent laser beams 915, 920 may be, for example, a UV laser (e.g., 325 nm HeCd laser). The resulting index pattern in a suitable material 905 may have, for example, a spatial period of 162.5 nm/index (325 nm), which may be much shorter than the operating wavelength of approximately, for example, 800 nm. The index (325 nm) is the index of the material 905 at the HeCd laser wavelength.

The wave plate material 905 used for the quarter wave plate 900 may be a polymer or glass material with photosensitivity where intensity non-uniformities give rise to an index grating, or a photoresist material that can be chemically etched and the remaining structure bleached so as to give rise to a very high contrast index grating. Under these conditions, birefringence may be exhibited at 800 nm and longer wavelengths, wherein the polarization of laser light parallel to the grating vector sees a lower index than the polarization that is perpendicular to the grating vector. By changing the incidence directions of the laser beams used to write the grating, the resulting fast axis (lower index axis) and slow axis can be reversed.

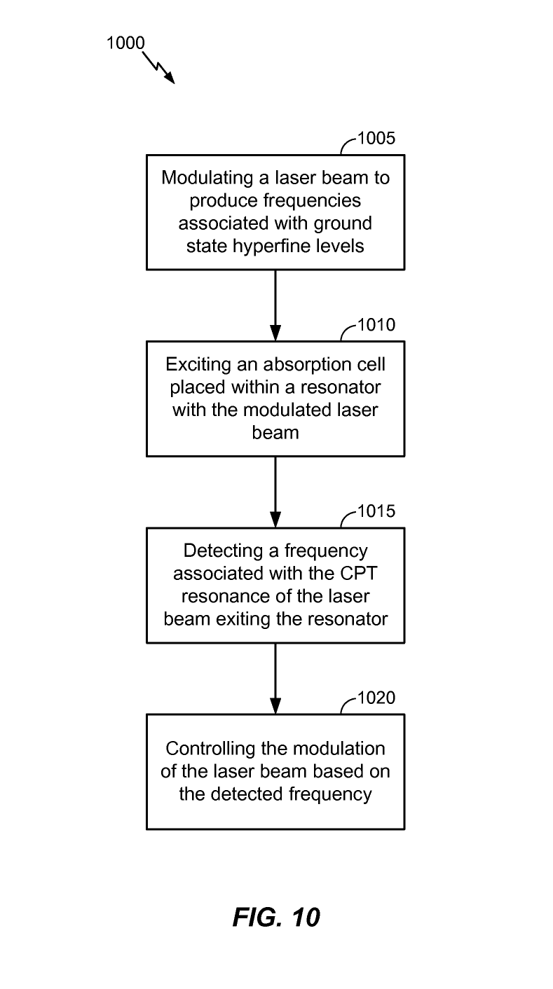

FIG. 10 is a flow chart illustrating a method 1000 for generating a reference oscillating signal based on Coherent Population Trapping (CPT). The method initially modulates a laser beam to produce frequencies associated with ground state hyperfine transition levels (Block 1005). This modulation is performed to produce a laser light having peak amplitude components at two different frequencies. The difference in these two frequencies corresponds to differences in the ground state hyperfine levels of the atoms in the absorption cell. The modulated laser beam may be produced by a modulated laser source (e.g., 405A or 405B). Next, the modulated laser beam excites at least one absorption cell placed within a resonator (Block 1010). The excitation may be performed within a resonator, such as an optical ring resonator 700 or an FP resonator 415. In the embodiment, the modulated laser source is not located in the resonator, but is external to the resonator. A detector may then detect the frequency associated with the CPT resonance of the laser light exiting the resonator (Block 1015). The detection may be performed by a photo detector. Finally, a frequency controller (e.g., 435) may control the modulation of the laser beam based on the detected frequency (Block 1020). This control permits the CASC to lock onto the f_{HFS}, and thus provide a very accurate RF reference oscillator signal.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for generating a reference oscillating signal based on Coherent Population Trapping (CPT) resonance. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A microfabricated atomic clock to generate a Coherent Population Trapping (CPT) resonance, comprising:
a Fabry-Perot (FP) resonator defining a cavity and configured to enhance a modulation term of a transmittance;
a first quarter wave plate adjacent to a first side of the FP resonator;
an absorption cell disposed inside the cavity of the FP resonator;
a second quarter wave plate adjacent to a second side of the FP resonator;
a modulated laser source disposed external to the FP resonator to output a laser beam, wherein the laser beam passes through the first quarter wave plate to excite the FP resonator and the absorption cell such that laser light exits from the FP resonator;
a detector configured to determine a frequency associated with the CPT resonance of the laser light exiting the FP resonator and passing through the second quarter wave plate; and
a frequency controller functionally coupled to the detector, which adjusts the modulated laser source based on the determined frequency.

2. The microfabricated atomic clock of claim 1, wherein the absorption cell has a volume less than 0.1 mm³.

3. The microfabricated atomic clock of claim 1, wherein the absorption cell is located at a peak of a standing wave in the cavity of the FP resonator.

4. The microfabricated atomic clock of claim 3, further comprising:
a plurality of absorption cells placed within the cavity of the FP resonator, wherein each absorption cell is located at a different peak of the standing wave.

5. The microfabricated atomic clock of claim 1, wherein the cavity of the FP resonator has a length of multiple half-wavelengths of the laser beam provided by the modulated laser source.

6. The microfabricated atomic clock of claim 1, wherein the first and second quarter wave plates are fabricated using holographically produced birefringence.

7. The microfabricated atomic clock of claim 6, wherein each of the first and second quarter wave plates comprises a material exposed with two counter-propagating laser beams passing there-through to form a high spatial frequency index grating, said grating having a 45 degree angle with respect to a Transverse-Electric (TE) wave orientation of the laser beam provided by the modulated laser source.

8. The microfabricated atomic clock of claim 7, wherein intensity non-uniformities in the material permit a forming of the grating.

9. The microfabricated atomic clock of claim 1, wherein the modulated laser source further comprises:
a first laser diode to generate a first laser beam;
a second laser diode to generate a second laser beam;
a phase locking module to maintain a phase coherence of the first laser beam and the second laser beam;
a frequency modulator to modulate a frequency of the second laser beam based on an output of the frequency controller; and
a combiner to superimpose the first laser beam and the frequency modulated second laser beam.

10. The microfabricated atomic clock of claim 9, wherein the combiner comprises a beam splitter.

11. The microfabricated atomic clock of claim 9, wherein the combiner comprises a cavity of the first laser diode.

12. The microfabricated atomic clock of claim 1, wherein the modulated laser source further comprises:
a laser diode to generate the laser beam; and
an amplitude modulator to modulate an amplitude of the laser beam based on the frequency controller.

13. The microfabricated atomic clock of claim 1, wherein the absorption cell is a vapor cell.

14. The microfabricated atomic clock of claim 13, wherein the vapor cell comprises Cesium or Rubidium.

15. The microfabricated atomic clock of claim 13, wherein the absorption cell is a solid state cell.

16. The microfabricated atomic clock of claim 1, wherein the cavity extends into a surface of at least one partially reflecting mirror within the FP resonator.

17. The microfabricated atomic clock of claim 1, wherein the cavity further comprises a bulk dielectric having periodic holes forming a lattice in three dimensions, wherein a defect in the lattice allows light to be localized leading to resonance.

18. A microfabricated atomic clock to generate a Coherent Population Trapping (CPT) resonance, comprising:
a resonator configured to enhance a modulation term of a transmittance;
an absorption cell disposed inside the resonator;
a first quarter wave plate associated with a first side of the absorption cell;
a second quarter wave plate associated with a second side of the absorption cell;
a modulated laser source disposed external to the resonator to output a laser beam, wherein the laser beam passes through the first quarter wave plate to excite the resonator and the absorption cell such that laser light exits from the resonator and passes through the second quarter wave plate;
a detector configured to determine a frequency associated with a CPT resonance of the laser light passing through the second quarter wave plate; and
a frequency controller functionally coupled to the detector, which adjusts the modulated laser source based on the determined frequency.

19. The microfabricated atomic clock of claim 18, wherein the resonator comprises:
a ring resonator waveguide coupled to an input waveguide through an evanescent coupling, wherein the input waveguide is coupled to the modulated laser source at one end and the detector at an opposite end.

20. The microfabricated atomic clock of claim 18, wherein the resonator comprises:
a Fabry-Perot (FP) resonator configured to enhance a modulation term of a transmittance.

21. The chip scale atomic clock of claim 18, wherein the absorption cell has a volume less than 0.1 mm³.

22. A method of generating a reference oscillating signal based on a Coherent Population Trapping (CPT) resonance, comprising:
modulating a laser beam to produce frequencies associated with ground state hyperfine transition levels;
exciting an absorption cell disposed within a resonator with the modulated laser beam, wherein a source for the modulated laser beam is external to the resonator;
detecting a frequency associated with the CPT resonance of laser light exiting the resonator; and
controlling the modulation of the laser beam based on the detected frequency.

23. The method of claim 22, wherein the absorption cell has a volume less than 0.1 mm³.

24. The method of claim 22, further comprising:
controlling the modulated laser beam to stabilize the detected frequency at a frequency corresponding to the CPT resonance.

25. The method of claim 22, wherein modulating the laser beam further comprises:
modulating an amplitude of the laser beam to produce frequency components having peaks at two separate frequencies, wherein a difference between the two separate frequencies corresponds to differences in the ground state hyperfine transition levels of atoms in the absorption cell.

26. The method of claim 22, wherein modulating the laser beam further comprises:
maintaining a phase coherence between a first laser beam and a second laser beam;
shifting a frequency of the second laser beam; and
superimposing the first laser beam and the frequency shifted second laser beam.

27. An apparatus to generate a reference oscillating signal based on a Coherent Population Trapping (CPT) resonance, comprising:
means for modulating a laser beam to produce frequencies associated with ground state hyperfine transition levels;
means for exciting an absorption cell placed within a resonator with the modulated laser beam, wherein a source for the modulated laser beam is external to the resonator;
means for detecting a frequency associated with a CPT resonance of laser light exiting the resonator; and
means for controlling the modulation of the laser beam based on the detected frequency.

28. The apparatus of claim 27, wherein the absorption cell has a volume less than 0.1 mm³.

29. The apparatus of claim 27, further comprising:
means for controlling the modulated laser beam to stabilize the detected frequency at a frequency corresponding to the CPT resonance.

30. The apparatus of claim 27, wherein the means for modulating the laser beam further comprises:
means for modulating an amplitude of the laser beam to produce frequency components having peaks at two separate frequencies, wherein a difference between the two separate frequencies corresponds to differences in the ground state hyperfine transition levels of atoms in the absorption cell.

31. The apparatus of claim 27, wherein the means for modulating the laser beam further comprises:
means for maintaining a phase coherence between a first laser beam and a second laser beam;
means for shifting a frequency of the second laser beam; and
means for superimposing the first laser beam and the frequency shifted second laser beam.
